(19) United States
(12) Patent Application Publication
(10) Pub. No.: US 2025/0320629 A1
(43) Pub. Date: Oct. 16, 2025

(54) Apparatus and Method for Growth of Two-Dimensional Crystal Material

(71) Applicant: WuHan University, Hubei (CN)

(72) Inventors: Zhaodong Li, Wuhan (CN); Chaoyu Chen, Wuhan (CN); Jiulong Li, Wuhan (CN); Haonan Song, Wuhan (CN); Lirong Wang, Wuhan (CN); Youquan Jiang, Wuhan (CN); Sheng Liu, Wuhan (CN)

(21) Appl. No.: 19/011,793

(22) Filed: Jan. 7, 2025

(30) Foreign Application Priority Data
Apr. 12, 2024 (CN) 202410437019.6

(51) Int. Cl. C30B 25/16; C30B 29/10; C30B 29/64

(52) U.S. Cl. CPC C30B 25/16; C30B 29/10; C30B 29/64

(57) ABSTRACT

An apparatus and method for growth of a two-dimensional crystal material are provided. In a single atomic layer deposition cycle of atomic layer deposition, a two-dimensional amorphous film is deposited by a deposition unit. The nuclear bond breaking, bonding, and atomic arrangement on the surface of the deposited two-dimensional amorphous film are controlled by a laser system, which transforms the deposited two-dimensional amorphous film into a two-dimensional crystal film. In a deposition process, monitoring result information from a monitoring unit is received by an upper computer, which adjusts at least one of parameters of the laser system and the deposition unit in real-time according to the monitoring result information.

### CROSS-REFERENCE TO RELATED APPLICATIONS

This patent application claims priority to China Patent Application No. 202410437019.6, filed on Apr. 12, 2024 and entitled “Apparatus and method for growth of two-dimensional crystal material,” which is hereby incorporated by reference herein as if reproduced in its entirety.

### TECHNICAL FIELD

The present application relates to the technical field of atomic layer deposition (ALD), and particularly, relates to an apparatus and method for growth of two-dimensional crystal materials.

### BACKGROUND

Atomic layer deposition is a vapor-phase film technology characterized by surface chemical reactions and self-limiting growth, allowing for precise control of film thickness, with accuracy exceeding 0.1 nm. While ALD yields films with exceptional uniformity and precise thickness control, the crystalline quality of these films, particularly for two-dimensional materials, is often inadequate; and materials deposited via ALD tend to be predominantly amorphous.

To convert these two-dimensional amorphous materials into crystalline forms, ultra-fast laser manipulation is employed, which facilitates atomic bond breaking, bonding, and rearrangement on the deposition surface. However, in current methodologies for fabricating two-dimensional crystalline materials using ALD technology, amorphous films are typically deposited first, followed by a transfer to a separate laser apparatus for crystallization. This division into two independent processes complicates the overall operation, increases the time required to achieve two-dimensional crystal materials, and diminishes growth efficiency. Moreover, the transfer of materials can compromise the vacuum environment essential for preserving the properties of sensitive materials, such as MoS₂ and HfS₂, leading to oxidation issues.

Additionally, existing techniques for growing two-dimensional crystal materials via ALD require that relevant parameters be set in advance. Once established, these parameters cannot be adjusted in real time during the film growth process. Should a change be necessary, the growth must be interrupted, and the parameters manually modified, resulting in a lack of dynamic regulation and control. Consequently, this rigidity limits the potential for enhancing the crystallization quality of two-dimensional thin film materials.

### SUMMARY

Technical advantages are generally achieved, by embodiments of this disclosure which describe apparatus and method for growth of two-dimensional crystal materials.

Accordingly, embodiments of the present application provide an apparatus and method for producing two-dimensional (2D) crystal films through the integration of real-time laser control with ALD, benefiting advanced material fabrication. The apparatus, which includes the components of the upper computer with real-time feedback, laser system, deposition unit with vacuum box and monitoring unit, integrates laser manipulation with atomic layer deposition (ALD) to crystallize two-dimensional (2D) amorphous films in real-time, improving efficiency and film quality. The method for 2D crystal growth comprises the steps of:

(a) Depositing a 2D amorphous layer using ALD.

(b) Using laser manipulation to achieve a crystalline film structure.

(c) Continuously adjusting parameters based on monitoring feedback to refine film crystallinity and uniformity.

In some embodiments, the apparatus includes an upper computer, a laser system and an atomic layer deposition system, wherein the upper computer is respectively in communication with the laser system and the atomic layer deposition system. The atomic layer deposition system comprises a deposition unit and a monitoring unit. During a single atomic layer deposition cycle of atomic layer deposition, the deposition unit is configured to deposit a two-dimensional amorphous film, and the laser system is configured to control atomic bond breaking, bonding and atomic arrangement on a surface of the deposited two-dimensional amorphous film, to transform the deposited two-dimensional amorphous film into a two-dimensional crystal film. In a deposition process, the upper computer is configured to receive monitoring result information from the monitoring unit, and carry out real-time adjustment and control on at least one of parameters of the laser system and deposition unit according to the monitoring result information.

In some embodiments, a method of growing the two-dimensional crystal material using the apparatus includes: during the single atomic layer deposition cycle, depositing, by use of the deposition unit, to form the two-dimensional amorphous film; and controlling, by use of the laser system, atomic bond breaking, bonding, and atomic arrangement on the surface of the two-dimensional amorphous film, to transform the two-dimensional amorphous film into the two-dimensional crystal film. The method may further include: during the deposition process, receiving, by use of the upper computer, the monitoring result information from the monitoring unit, and adjusting, in real-time, at least one parameter of the laser system or the deposition unit based on the received monitoring result information.

Compared with traditional atomic layer deposition (ALD) to crystallize two-dimensional (2D) amorphous films, embodiments of the application have advantages of efficient crystallization, real-time laser control, continuous monitoring feedback and material versatility.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is an overall schematic diagram of an apparatus for growth of a two-dimensional crystal material provided by an embodiment of the present application;

FIG. 2 is a schematic diagram of an atomic layer deposition part in an apparatus for growth of a two-dimensional crystal material provided by an embodiment of the present application;

FIG. 3 is a schematic diagram of an ultrafast laser part of an apparatus for growth of a two-dimensional crystal material provided by an embodiment of the present application;

FIG. 4 is a diagram of laser spot shape change corresponding to an apparatus for growth of a two-dimensional crystal material provided by an embodiment of the present application;

FIG. 5 is a block diagram of monitoring feedback control corresponding to an apparatus for growth of two-dimensional crystal material provided by an embodiment of the present application;

FIG. 6 is a schematic diagram of film growth monitoring corresponding to an apparatus for growth of a two-dimensional crystal material provided by an embodiment of the present application; and

FIG. 7 is a schematic diagram of temperature monitoring corresponding to an apparatus for growth of a two-dimensional crystal material provided by an embodiment of the present application.

The following provides parts and their corresponding numeral numbers used in the drawings:

| # | PART |
|---|---|
| 1 | Ultrafast laser |
| 2 | Collimating beam expander |
| 3 | Beam shaper |
| 4 | Baffle |
| 5 | Field mirror |
| 6 | First air inlet |
| 7 | Second air inlet |
| 8 | Transparent plate |
| 9 | Infrared camera |
| 10 | X-ray diffractometer |
| 11 | Substrate |
| 12 | Tail gas treatment equipment |
| 13 | Reflection high-energy electron diffractometer |
| 14 | Optical fiber pyrometer |
| 15 | Vacuum box |
| 16 | First precursor and inert gas source |
| 17 | Second precursor and inert gas source |
| 18 | Upper computer |

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of embodiments of this disclosure are discussed in detail below. It should be appreciated, however, that the concepts disclosed herein may be embodied in a wide variety of specific contexts, and that the specific embodiments discussed herein are merely illustrative and do not serve to limit the scope of the claims. Further, it should be understood that various changes, substitutions and alterations may be made herein without departing from the spirit and scope of this disclosure as defined by the appended claims.

The present application addresses several significant challenges associated with the preparation of two-dimensional (2D) crystal materials using atomic layer deposition (ALD), including lengthy preparation times, low growth efficiency, oxidation during material transfer, and limitations in crystallization quality. By introducing a novel apparatus and method for growing 2D crystal materials, the application enhances growth efficiency and improves material quality.

The apparatus includes an upper computer, a laser system, and an atomic layer deposition system. The upper computer communicates with both the laser system and the ALD system, which includes a deposition unit and a monitoring unit. During each single atomic layer deposition cycle, the deposition unit deposits a 2D amorphous film, while the laser system controls atomic bond breaking, bonding, and arrangement on the film's surface, facilitating the transformation of the amorphous film into a crystalline form. Throughout the deposition process, the upper computer receives monitoring data from the monitoring unit, enabling real-time regulation of parameters within both the laser system and the deposition unit based on this data.

In an embodiment, the laser system features an ultrafast laser and a field mirror. The ultrafast laser emits beams that are directed by the field mirror, which adjusts the laser's emission range to irradiate the surface of the deposited film effectively.

Furthermore, the laser system may include a collimating beam expander, a beam shaper, and a baffle, arranged sequentially along the optical path between the ultrafast laser and the field mirror. The collimating beam expander serves to expand and collimate the ultrafast laser beam, while the beam shaper modifies the laser spot shape from circular to rectangular. The baffle helps to block the edges of the rectangular light spot, resulting in a more homogenized laser beam.

The deposition unit is designed with a vacuum box containing the substrate, precursor, and gas assembly. The substrate is positioned within the vacuum box, which features an air inlet connecting to the precursor and gas assembly. A transparent plate at the top of the vacuum box allows the laser beam emitted by the laser system to irradiate the deposited film's surface after passing through. Additionally, the monitoring unit is installed on the vacuum box to facilitate accurate tracking of the deposition process.

The precursor and gas assembly consist of a first and second precursor, each paired with an inert gas source, and a tail gas treatment equipment. The vacuum chamber is equipped with two separate air inlets-one for each precursor and its corresponding inert gas. The first precursor and inert gas enter the vacuum box through the first air inlet, allowing the precursor to react with the substrate surface. The inert gas then purges any excess precursor and gaseous by-products into the tail gas treatment equipment. Similarly, the second precursor, along with its inert gas, is introduced through the second air inlet. This precursor either reacts with the previously adsorbed first precursor or with the reaction products from the initial precursor's interaction with the substrate. The inert gas from the second inlet subsequently flushes out any residual precursor and by-products into the tail gas treatment equipment. This setup ensures precise control over precursor delivery, reaction processes, and by-product removal within the vacuum chamber.

The monitoring unit ideally includes an X-ray diffractometer, a reflection high-energy electron diffractometer, an infrared camera, and an optical fiber pyrometer, each serving a specific purpose in real-time analysis and control of the deposition process. The X-ray diffractometer provides first monitoring data by analyzing the film's material composition, as well as the atomic or molecular structure and morphology within the film. The reflection high-energy electron diffractometer delivers second monitoring information by assessing surface structure and smoothness of the deposited film. The infrared camera monitors the substrate temperature within the deposition unit, generating third monitoring data crucial for thermal management. Meanwhile, the optical fiber pyrometer focuses on the transient temperature within the laser-irradiated area of the deposited film, yielding fourth monitoring information. Together, these monitoring inputs enable comprehensive feedback for precise control and adjustment of deposition parameters, ensuring optimal film quality and consistency.

Ideally, a notch filter is integrated into the infrared camera, with its wavelength precisely matched to that of the laser system, thereby enhancing temperature monitoring accuracy by filtering out laser interference.

Key parameters of the laser system include adjustable settings such as laser energy and ultrafast laser spot size, allowing for precise control over the crystallization process. In the deposition unit, essential parameters such as gas inlet rate and inlet timing for atomic layer deposition are optimized to improve film growth and consistency.

The apparatus for synthesizing two-dimensional crystal materials is especially suited for producing high-quality two-dimensional films, including graphene and metal sulfide crystal films, broadening the scope of its application in advanced material fabrication.

The application presents several significant technical advantages, primarily through the integration of laser manipulation within the atomic layer deposition (ALD) process. During a single ALD cycle, a two-dimensional amorphous film is deposited by the deposition unit. This film undergoes transformation into a crystalline structure as the laser system precisely controls the breaking and forming of atomic bonds and the arrangement of atoms on the film's surface. Real-time monitoring data from the monitoring unit is relayed to the upper computer, allowing for dynamic adjustments of at least one parameter within the laser system or the deposition unit based on this feedback.

By incorporating laser manipulation into the ALD process, the application enhances the crystallization of the two-dimensional amorphous film. The ultrafast laser facilitates localized atomic-level control, enabling not only post-deposition processing to convert the amorphous film into a crystalline one but also simultaneous manipulation during the deposition itself. This innovative approach allows the laser process to become an integral part of the ALD sequence, effectively transforming it into a continuous flow for the deposition of two-dimensional crystal materials.

The ultrafast laser operates within the vacuum chamber of the ALD apparatus, improving growth efficiency and reducing preparation time. Furthermore, it mitigates the oxidation risks associated with easily oxidizable materials, such as MoS₂ and HfS₂, which traditionally suffer from environmental exposure during transfers between ALD and laser processing stages.

Moreover, the monitoring unit enables real-time assessment of the thin film during deposition. This information is transmitted to the upper computer, which can promptly adjust ALD and laser parameters, thus enhancing the crystallization quality of the two-dimensional film. Such adjustments allow for effective control over phase transformations, defect management, and component uniformity, ultimately facilitating the preparation of high-quality two-dimensional crystal materials. The application's versatility extends beyond two-dimensional metal sulfide crystal films, making it applicable to a broad range of two-dimensional materials.

### Embodiment 1

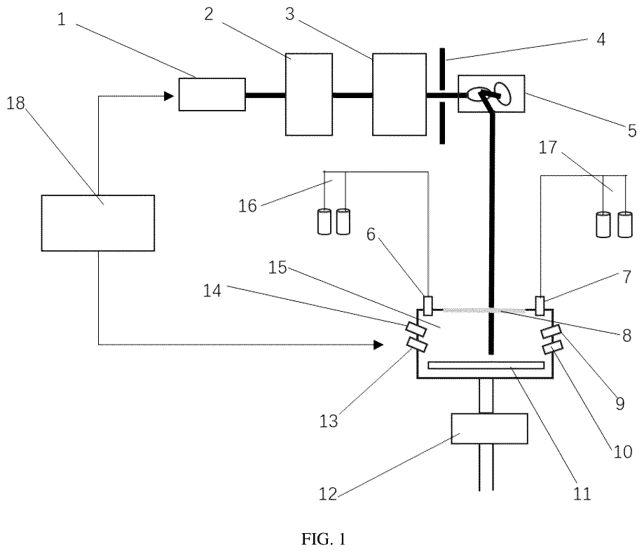

Embodiment 1 provides an apparatus for growth of two-dimensional crystal material, referring to FIGS. 1 to 7, including an upper computer 18, a laser system and an atomic layer deposition system. The upper computer 18 is respectively communicated with the laser system and the atomic layer deposition system, and the atomic layer deposition system comprises a deposition unit and a monitoring unit. In the single atomic layer deposition period of atomic layer deposition, the deposition unit is used to deposit and form a two-dimensional amorphous film, and the laser system is used to control the atomic bond breaking, bonding and atomic arrangement on the surface of the deposited film, so that the deposited two-dimensional amorphous film becomes a two-dimensional crystal film. During the deposition process, the upper computer 18 receives the monitoring result information from the monitoring unit, and adjusts at least one of the parameters of the laser system and the parameters of the deposition unit in real time according to the monitoring result information.

The laser system comprises an ultrafast laser 1 and a field mirror 5 (namely an F-Theta lens). The ultrafast laser 1 is used to emit ultrafast laser beams, and the field mirror 5 is used to adjust the emission range of ultrafast laser beams, and the ultrafast laser beams emitted through the field mirror 5 irradiate the surface of the deposited film.

In addition, the laser system may also include a collimating beam expander 2, a beam shaper 3 and a baffle 4 which are sequentially arranged on the optical path between the ultrafast laser 1 and the field mirror 5. The collimating beam expander 2 is used to expand the ultrafast laser beam and collimate the ultrafast laser beam. The beam shaper 3 is used for adjusting the spot shape of the ultrafast laser beam from a circular spot to a rectangular spot. The baffle 4 is used to block the edge of the rectangular light spot to obtain a homogenized ultrafast laser beam.

The deposition unit comprises a vacuum box 15, a substrate 11, a precursor and a gas component. The substrate 11 is arranged in the vacuum box 15, and the vacuum box 15 is provided with an air inlet, and the precursor and the gas assembly are communicated with the vacuum box 15 through the air inlet. A transparent plate 8 (for example, transparent glass) is installed on the top of the vacuum box 15, and the laser beam emitted by the laser system irradiates the surface of the deposited film after passing through the transparent plate 8. The monitoring unit is installed on the vacuum box 15.

Specifically, the precursor and gas assembly includes a first precursor and inert gas source 16, a second precursor and inert gas source 17 and a tail gas treatment equipment 12. The vacuum box 15 is provided with a first air inlet 6 and a second air inlet 7. The first precursor and the first precursor in the inert gas source 16 enter the vacuum box 15 through the first gas inlet 6 to react with the surface of the substrate 11. The first precursor and the first inert gas in the inert gas source 16 are introduced into the vacuum box 15 through the first gas inlet 6, and the redundant first precursor and gas-phase by-products are purged into the tail gas treatment equipment 12 by the first inert gas. The second precursor and the second precursor in the inert gas source 17 enter the vacuum box 15 through the second gas inlet 7 to react with the first precursor adsorbed on the surface of the substrate 11, or continue to react with the product of the reaction between the first precursor and the substrate 11. The second precursor and the second inert gas in the inert gas source 17 are introduced into the vacuum box 15 through the second gas inlet 7, and the redundant second precursor and gas phase by-products are purged into the tail gas treatment equipment 12 by the second inert gas.

The monitoring unit comprises an X-ray diffractometer 10 (namely X-ray Diffraction, XRD) and a reflection high-energy electron diffractometer 13 (namely reflection high-energy electron diffraction, RHEED. Specifically, ultra-fast RHEED), infrared camera 9 and optical fiber pyrometer 14 may be used. The X-ray diffractometer 10 is used for monitoring at least one of the material composition of the deposited film, the structure of atoms or molecules inside the material and the morphology of atoms or molecules inside the material, and obtaining first monitoring information. The reflective high-energy electron diffractometer 13 is used for monitoring at least one of the surface structure of the deposited film and the smoothness of the surface of the deposited film, and obtaining second monitoring information. The infrared camera 9 is used for monitoring the temperature of the substrate in the deposition unit and obtaining third monitoring information. The optical fiber pyrometer 14 is used to monitor the transient temperature of the deposited film in the laser irradiation area and obtain the fourth monitoring information. The monitoring result information includes the first monitoring information, the second monitoring information, the third monitoring information and the fourth monitoring information.

In addition, the infrared camera 9 may also be equipped with a notch filter, the wavelength of which corresponds to the wavelength selected by the laser system, and the influence of laser on its temperature monitoring results may be eliminated by using the notch filter.

The parameters of the laser system include at least one of laser energy and spot size of ultrafast laser. The parameters of the deposition unit include at least one of the gas inlet rate and gas inlet time for atomic layer deposition.

Specifically, the upper computer 18 may control the parameters of atomic layer deposition, such as air intake rate, air intake time, laser energy and spot size of ultrafast laser, and control the atomic arrangement, defects, components, etc. of a single deposition layer in real time based on the feedback results of the X-ray diffractometer 10, the reflective high-energy electron diffractometer 13, the infrared camera 9 and the optical fiber pyrometer 14 and the relationship model between the above results and atomic layer deposition parameters and ultrafast laser parameters, so as to obtain high-quality two-dimensional crystal materials.

The two-dimensional crystal film obtained by the apparatus for preparing the two-dimensional crystal material is a two-dimensional graphene crystal film material or a two-dimensional metal sulfide crystal film material (for example, gallium sulfide GaS, hafnium disulfide HfS₂, molybdenum disulfide MoS₂ and tin disulfide SnS₂).

Embodiment 1 uses ultrafast laser to improve the crystal quality of atomic layer deposition thin films. Ultrafast laser may irradiate laser with high energy density into a small area of materials in a short time, and control the atomic bond breaking, bonding and atomic arrangement of materials in this area. The advantage of ultrafast laser is that the heating depth may be controlled by changing the laser wavelength in the vertical direction, and the accuracy may reach micron level, and the parallel direction may be controlled by changing the spot size and scanning path, thus realizing the accurate control of the laser control area. At the same time, the high energy density of laser makes it possible to achieve several thousand ° C./s heating rate and several ns or even ps heat treatment time, which can greatly shorten the required time compared with conventional heat treatment. Embodiment 1 can perform single-level precise control, and the ultrafast laser beam may be vertically irradiated to the surface of the deposited thin film by using the field mirror, so that the laser energy injected vertically is more uniform, and the temperature of the scanning area can be better controlled, which can be used for single-layer thin film annealing. The monitoring unit is added in Embodiment 1, which may monitor the grown thin film in real time and feedback the relevant data to the upper computer. Based on the above results, the upper computer may adjust and control the ALD and laser-related parameters in real time, which can effectively improve the crystallization quality of two-dimensional thin film materials, control the phase transformation of deposited materials, adjust and control the defects and components of thin films, and improve their uniformity. In Embodiment 1, laser is integrated into ALD process. Not only can laser be used as post-treatment process to change the deposited thin film from amorphous to crystalline, but also the crystalline thin film can be directly deposited by laser operation at the same time of deposition, which saves the intermediate conversion process of materials from deposition apparatus to post-treatment apparatus, saves the time needed to obtain two-dimensional crystalline materials, and also avoids the oxidation problem of oxidizable materials caused by the destruction of vacuum environment.

### Embodiment 2

Embodiment 2 provides a method for growth of two-dimensional crystal material, which is realized by using the apparatus for preparing the two-dimensional crystal material as described in Embodiment 1. The method for preparing the two-dimensional crystal material comprises the following steps: depositing a two-dimensional amorphous film by using a deposition unit within a single atomic layer deposition period of atomic layer deposition, and controlling atomic bond breaking, bonding and atomic arrangement on the surface of the deposited film by using a laser system to change the deposited two-dimensional amorphous film into a two-dimensional crystal film; In the deposition process, the monitoring result information from the monitoring unit is received by the upper computer, and at least one of the parameters of the laser system and deposition unit is adjusted in real time according to the monitoring result information.

Specifically, Embodiment 2 includes three parts: atomic layer deposition, ultrafast laser control and monitoring feedback control. The monitoring and feedback of the corresponding atomic layer deposition, laser-controlled crystallization and growth process may be intelligently controlled through an integrated system. In FIG. 1, the laser path is represented by the thick line from the ultrafast laser 1 to the vacuum box 15.

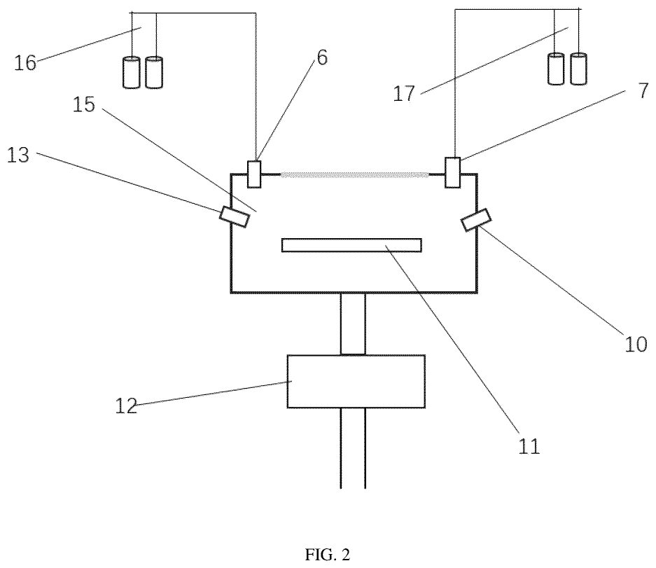

Referring to the schematic diagram of atomic layer deposition as shown in FIG. 1 and FIG. 2, under the control of the upper computer 18, the first precursor and the first precursor in the inert gas source 16 enter the vacuum box 15 through the first gas inlet 6 to react with the reaction site on the substrate 11, and then the first precursor and the first inert gas in the inert gas source 16 are introduced into the vacuum box 15 through the first gas inlet 6. The first inert gas is used to purge the redundant first precursor and gaseous by-products into the tail gas treatment apparatus 12, and then the second precursor and the second precursor in the inert gas source 17 are introduced into the vacuum box 15 through the second gas inlet 7 to react with the substrate on the second surface, and the surface is converted into the initial surface of the same reaction site. Finally, the second precursor and the second inert gas in the inert gas source 17 are introduced into the vacuum box 15 through the second gas inlet 7, and the unreacted second precursor and gas phase by-products are purged into the tail gas treatment apparatus 12. In this process, as shown in FIG. 6, the information such as the composition of the deposited film sample material, the structure or morphology of atoms or molecules in the material, etc. are monitored by the X-ray diffractometer 10. The crystal surface structure and the smoothness of the growth surface are observed by the reflective high-energy electron diffractometer 13, and the monitoring result data of the X-ray diffractometer 10 and the reflective high-energy electron diffractometer 13 will be uploaded to the upper computer 18 in real time.

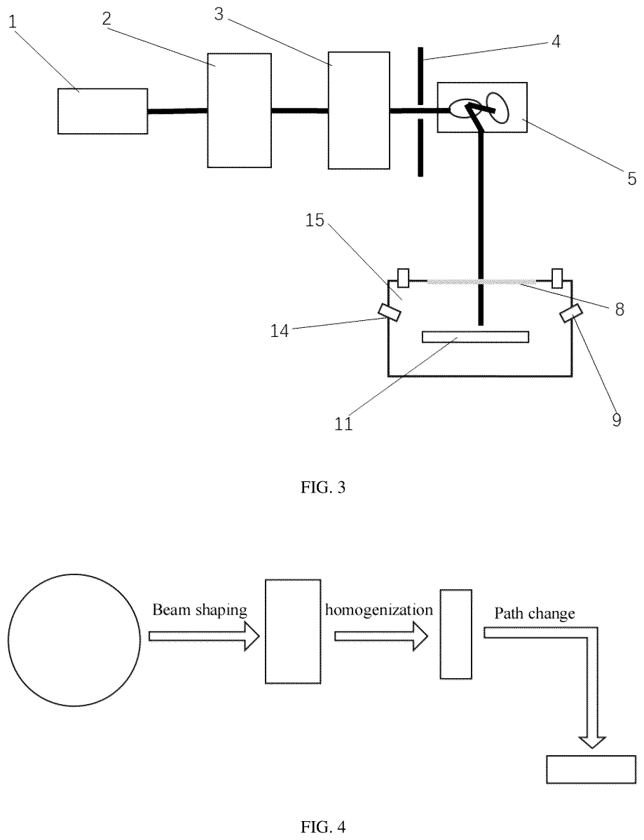

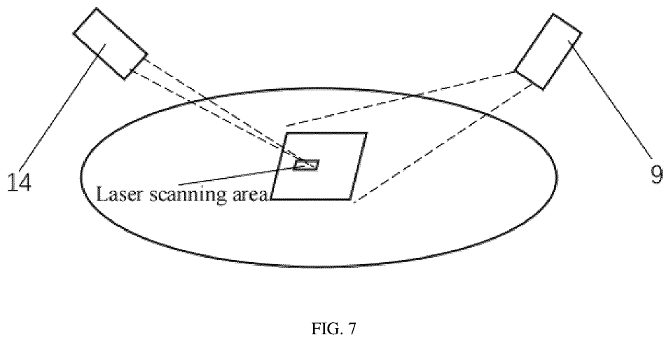

Referring to the ultrafast laser schematic diagram shown in FIG. 1 and FIG. 3, after the two-dimensional thin film material is deposited on the substrate 11, the laser beam emitted by the ultrafast laser 1 under the control of the upper computer 18 is changed in beam size and collimated and emitted, the laser beam shape is adjusted by the beam shaper 3 from a circular spot to a rectangular spot, and the edge of the rectangular spot is blocked by the baffle 4, at this time, the laser energy is changed from Gaussian distribution to uniform distribution. In order to achieve the purpose of laser homogenization, the homogenized laser beam enters the field mirror 5, and the angle adjustment range of the field mirror 5 may be determined by the size of the thin film sample obtained by atomic layer deposition. By adjusting the angle of the field mirror 5, the emission range of the laser beam is changed, as shown in FIG. 4. The laser emitted through the field mirror 5 irradiates the deposited thin film material through the transparent plate 8, and the ultra-fast laser scans the deposited thin film to control the atomic bond breaking, bonding and atomic arrangement on the deposition surface. Based on the chemical adsorption growth in the traditional atomic layer deposition cycle, the ultra-fast laser is used to realize the precise localized control of adsorbed atoms and improve the crystal quality of the thin film. In this process, refer to FIG. 7, and the infrared camera 9 is used to monitor the substrate temperature in real time. The optical fiber pyrometer 14 is used to monitor the transient temperature of the deposited sample in the laser irradiation area in real time, and the temperature monitoring result data of the infrared camera 9 and the optical fiber pyrometer 14 will be fed back to the upper computer 18 in real time.

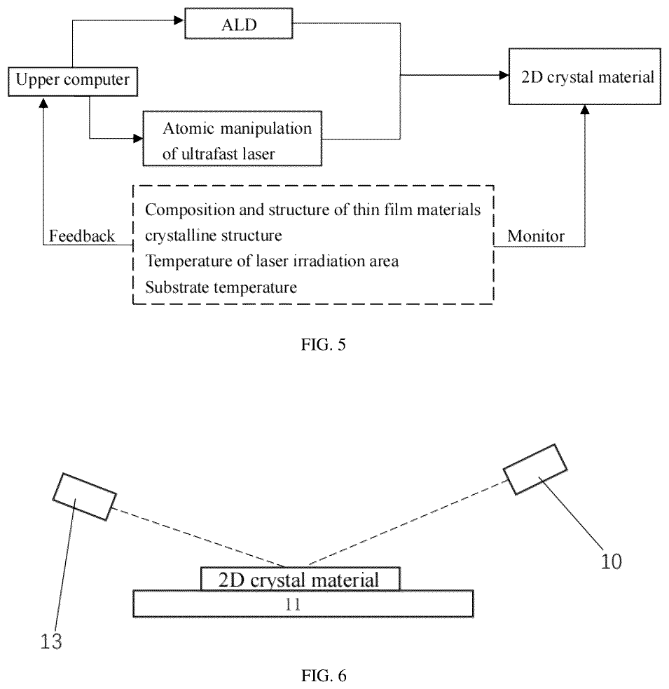

Referring to the schematic diagram of monitoring feedback control shown in FIG. 5 and FIGS. 1, 6 and 7, during the deposition process, the X-ray diffractometer 10, the reflected high-energy electron diffractometer 13, the infrared camera 9 and the optical fiber pyrometer 14 monitor the composition of the two-dimensional thin film material, the structure or morphology of atoms or molecules inside the material, the crystal structure, the substrate temperature and the thin film temperature in the laser irradiation area and feed back the monitoring results to the upper computer 18 in real time. Based on the feedback results, the upper computer 18 may adjust and control the parameters such as gas inlet rate and gas inlet time in the atomic layer deposition process and the parameters such as laser energy and spot size in the laser material enhancement process in real time, so as to control the atomic arrangement, defects and components of the single deposition layer and obtain high-quality two-dimensional crystal materials.

Referring to the schematic diagram of film growth monitoring as shown in FIG. 6, the X-ray diffractometer 10 diffracts a material by X-rays, analyzes its diffraction pattern, and obtains information such as the composition of the material, the structure or morphology of atoms or molecules inside the material, etc. The pulsed electron beam with a certain energy (usually 10-50 kev) emitted by the reflective high-energy electron diffractometer 13 strikes the sample surface at a grazing angle of 1˜3, and the penetration depth of the electron beam is only 1-2 atomic layers, which completely reflects the structural information of the sample surface, especially the thin film, rather than the substrate.

Referring to the schematic diagram of temperature monitoring shown in FIG. 7, the infrared camera 9 collects radiation from the whole substrate at a certain rate and monitors the substrate temperature in real time. The infrared camera 9 is equipped with a notch filter whose wavelength is the wavelength of the selected laser to eliminate the influence of laser on its monitoring results. The optical fiber pyrometer 14 collects radiation in a certain area at a certain rate and monitors the transient temperature at a specific point, which can monitor the temperature change in the laser scanning area on the thin film in real time.

Embodiment 2 will be further explained in a step-by-step manner, and the method includes the following steps:
Step 1, under the control of an upper computer, introducing a first precursor and the first precursor in an inert gas source into a vacuum box to react with a reaction site on a substrate;
Step 2, introducing the first precursor and the first inert gas in the inert gas source into a vacuum box for purging, and removing the redundant first precursor and gas phase byproducts generated by the reaction;
Step 3, introducing a second precursor and a second precursor in an inert gas source into a substrate to perform a second surface reaction, and converting the surface into an initial surface with the same reaction site;
Step 4, introducing the second precursor and the second inert gas in the inert gas source into a vacuum box for purging to remove unreacted second precursor and gas phase by-products;
Step 5, the quality of the thin film sample is monitored in real time by using an X-ray diffractometer and a reflective high-energy electron diffractometer, and the result data is fed back to the upper computer, and the upper computer adjusts and controls the parameters such as the gas inlet rate and the gas inlet duration of atomic layer deposition in real time based on the feedback results;
Step 6, the upper compute controls the lase to start, the emitted laser passes through the collimate beam expander, the beam shaper, the baffle and the field lens, and then passes through the transparent plate on the upper surface of the vacuum box to irradiate the surface of the deposited film, and the ultra-fast laser scans the deposited film to control the atomic bond breaking, bonding and atomic arrangement on the deposited surface; and
Step 7: the infrared camera and fiber pyrometer are used to monitor the surface temperature of the deposited film on the substrate and the laser irradiation area in real time, and the result data are fed back to the upper computer in real time, and the upper computer adjusts and controls the laser energy, spot size and other parameters of the ultrafast laser in real time based on the feedback results.

The above workflow is just an example, and different circular-flow control combinations may be compiled according to actual needs, for example, step 1-step 7 may be performed circularly, step 1-step 4 may be repeated several times before step 5-step 7, or circular-flow combinations such as step 1-5-2-3-4-6 may be performed.

In Embodiment 2, laser manipulation was integrated into the atomic layer deposition process, and X-ray diffractometer, reflective high-energy electron diffractometer, infrared camera and optical fiber pyrometer were added to monitor and feedback the crystal growth process and temperature of the deposited thin film in real time, so as to adjust and control relevant parameters in real time and realize the preparation of high-quality two-dimensional crystal thin film samples.

The upper computer may be computer including one or more processors configured to read and execute instructions stored on a computer-readable storage device or media perform the methods described herein. A computer-readable storage device may include any non-transitory mechanism for storing information in a form readable by a machine (e.g., a computer). For example, a computer-readable storage device may include read-only memory (ROM), random-access memory (RAM), magnetic disk storage media, optical storage media, flash-memory devices, solid state storage media, and other storage devices and media.

Finally, it should be noted that the above specific embodiments are only used to illustrate the technical scheme of the present application, but not to limit it. Although the present application has been described in detail with reference to examples, those skilled in the art should understand that the technical scheme of the present application can be modified or replaced by equivalents without departing from the spirit and scope of the technical scheme, which should be included in the scope of the claims of the present application.

What is claimed:

1. An apparatus for growth of a two-dimensional crystal material, comprising:
an upper computer, a laser system and an atomic layer deposition system, wherein the upper computer is respectively in communication with the laser system and the atomic layer deposition system; and
wherein the atomic layer deposition system comprises a deposition unit and a monitoring unit;
during a single atomic layer deposition cycle of atomic layer deposition, the deposition unit is configured to deposit a two-dimensional amorphous film, and the laser system is configured to control atomic bond breaking, bonding and atomic arrangement on a surface of the deposited two-dimensional amorphous film, to transform the deposited two-dimensional amorphous film into a two-dimensional crystal film; and
in a deposition process, the upper computer is configured to receive monitoring result information from the monitoring unit, and carry out real-time adjustment and control on at least one of parameters of the laser system and deposition unit according to the monitoring result information.

2. The apparatus of claim 1, wherein the laser system comprises:
an ultrafast laser configured to emit ultrafast laser beams; and
a field mirror configured to adjust an emission range of the ultrafast laser beams, to direct the ultrafast laser beams onto the surface of the deposited two-dimensional amorphous film.

3. The apparatus of claim 2, wherein the laser system further comprises:
a collimating beam expander, a beam shaper, and a baffle sequentially arranged along an optical path between the ultrafast laser and the field mirror;
wherein the collimating beam expander is configured to expand the ultrafast laser beams and collimate the ultrafast laser beams;
the beam shaper is configured to transform shapes of light spots of the ultrafast laser beams from being circular to being rectangular; and
the baffle is configured to block edges of the rectangular light spots, to obtain homogenized ultrafast laser beams.

4. The apparatus of claim 1, wherein the deposition unit comprises:
a vacuum box, comprising an air inlet;
a substrate arranged in the vacuum box;
a precursor and gas assembly connected to the vacuum box via the air inlet; and
a transparent plate affixed to a top of the vacuum box, through which the ultrafast laser beams emitted by the laser system pass and reach the surface of the deposited two-dimensional amorphous film; and
wherein the monitoring unit is mounted on the vacuum box.

5. The apparatus of claim 4, wherein the precursor and gas assembly comprises a first precursor-inert gas source, a second precursor-inert gas source, and a tail gas treatment apparatus;
the vacuum box is provided with a first air inlet and a second air inlet;
the first precursor-inert gas resource is configured to provide:
a first precursor that enters the vacuum box via the first air inlet, and reacts with a surface of the substrate; and
a first inert gas that enters the vacuum box via the first air inlet, purging a redundant portion of the first precursor and a first gas-phase by-product into the tail gas treatment apparatus; and
the second precursor-inert gas resource is configured to provide:
a second precursor that enters the vacuum box via the second air inlet, and reacts with the first precursor adsorbed on the surface of the substrate, or reacts with a product generated from reaction of the first precursor and the substrate; and
a second inert gas that enters the vacuum box via the second air inlet, purging a redundant portion of the second precursor and a second gas-phase by-product into the tail gas treatment apparatus.

6. The apparatus of claim 1, wherein the monitoring unit comprises:
an X-ray diffractometer, configured to monitor at least one of following: a material composition of a deposited film, an atomic or molecular structure of a material, or an atomic or molecular morphology of a material, and to obtain first monitoring information;
a reflection high-energy electron diffractometer, configured to monitor at least one of following: a surface structure of a deposited film, or smoothness and flatness of a surface of the deposited film, and to obtain second monitoring information;
an infrared camera, configured to monitor a temperature of a substrate in the deposition unit and obtain third monitoring information; and
an optical fiber pyrometer, configured to monitor a transient temperature of the deposited film in a laser irradiation area and obtain fourth monitoring information; and
wherein the monitoring result information includes the first monitoring information, the second monitoring information, the third monitoring information and the fourth monitoring information.

7. The apparatus of claim 6, wherein the infrared camera comprises a notch filter, and a wavelength of the notch filter corresponds to a wavelength selected by the laser system.

8. The apparatus of claim 1, wherein,
a parameter of the laser system comprises at least one of laser energy of ultrafast laser or a light spot size of ultrafast laser; and
a parameter of the deposition unit comprises at least one of a gas intake rate or a gas intake duration of atomic layer deposition.

9. The apparatus of claim 1, wherein the two-dimensional crystal film is a two-dimensional graphene crystal film material or a two-dimensional metal sulfide crystal film material.

10. A method for growing the two-dimensional crystal material using the apparatus of claim 1, the method comprising:
during the single atomic layer deposition cycle,
depositing, by use of the deposition unit, to form the two-dimensional amorphous film; and
controlling, by use of the laser system, atomic bond breaking, bonding, and atomic arrangement on the surface of the two-dimensional amorphous film, to transform the two-dimensional amorphous film into the two-dimensional crystal film; and
during the deposition process, receiving, by use of the upper computer, the monitoring result information from the monitoring unit, and adjusting, in real-time, at least one parameter of the laser system or the deposition unit based on the received monitoring result information.
